(19) United States
(12) Patent Application Publication
(10) Pub. No.: US 2007/0103177 A1
(43) Pub. Date: May 10, 2007

(54) Probes of probe card and the method of making the same

(75) Inventor: Chih-Chung Chen, Taipei City (TW)

Correspondence Address: BROWDY AND NEIMARK, P.L.L.C.;624 NINTH STREET, NW, SUITE 300, WASHINGTON, DC, 20001-5303, US

(73) Assignee: MJC Probe Incorporation, Chu-Pei City (TW)

(21) Appl. No.: 11/507,443

(22) Filed: Aug. 22, 2006

(30) Foreign Application Priority Data
Nov. 10, 2005 (TW) 94139474

(51) Int. Cl. G01R 31/02

(52) U.S. Cl. 324/754

(57) ABSTRACT

The present invention provides probes of a probe card and the method of making the same, which is easier to control the size and hardness of each probe and provides the probes with well strength, hardness and electric property. The probe has a main member with a suspended arm, at least one conductive layer on the suspended arm and a dielectric layer between the conductive layer and the suspended arm. The conductive layer(s) is/are stacked on the suspended arm of the main member by electrocasting process and grinded to control the total thickness of the suspended arm.

### BACKGROUND OF THE INVENTION

1. Field of the Invention

The present invention relates generally to a probe card, and more particularly to probes of a probe card and the method of making the same.

2. Description of the Related Art

Conventional probes of a probe card are made of metal. Because of the decrease of the pad pitches of semiconductor wafers, packages and panels, the sizes of the probes have to be decreased as well. The stress of the probes pressing the pads of the semiconductor wafer is increased when the sizes of the probes are decreased. As a result, the probes will deform or damage after a long time of use that breaks the flatness of the probes and affects the probes working in the test. It is an important issue to decrease the sizes of the probes and keep them with a strong mechanical strength.

U.S. Pat. No. 6,414501, 6,507,204 and 6,864,695 taught silicon probes with a metal coating thereon. The silicon has a well capacity of anti-fatigue and the metal coating protects the silicon from break and provides a well electrical conduction. These inventions can not keep the metal coatings on every silicon probes with a uniform thickness so that the probes have different hardness. In the test of wafers, the contact resistances between the probes and the pads are different that affects the accuracy of test.

Another invention of U.S. Pat. No. 6,359,454 taught probes of silicon and metal. The probes have well mechanical strength. The semiconductor process is applied to make the metal part of the probe and grinding process is applied to control the sizes of the probes. In the process of fabrication, the probes are obliquely mounted on a substrate that makes it hard to control the precise locations of the probes. As the increase of the number of the probes, it has a worse location control of the probes. In addition, the shapes of tips of the probes of the invention are the same that can't be designed individually to have various shapes for specific requirement. Furthermore, the parts under the probes are removed by anisotropic chemical etching. The etching process is hard to control so that the probes usually have different suspended lengths to make the probes with various hardness. This will make the contact resistances between the probes and the pads different that affects the accuracy of test much.

In conclusion, the conventional probes have problems of inconsistence of hardness, poor resistance and electrical character or poor location control of probes, fine pitch and stable electrical character because of the process of fabrication.

### SUMMARY OF THE INVENTION

The primary objective of the present invention is to provide probes of a probe card, which have strong mechanical strength, uniform hardness and well.

The secondary objective of the present invention is to provide a method of making probes of a probe card, which is easy to control the hardness and electrical character of the probes.

According to the objectives of the present invention, a probe of a probe card comprises a main member, at least one conductive layer and a tip. The main member has a suspended arm with a surface. The at least one conductive layer is provided on the surface of the suspended arm. The tip is provided on one of the at least one conductive layer and electrically connected to the conductive layer.

To fabricate the probe of the present invention, the main member is made first, and then providing a dielectric layer on the main member. The conductive layer is provided on the dielectric layer by electrocasting, and then grinding the conductive layer. At least, processing the main member to form the structure of the probe. Another method of making the probe of the present invention is providing the conductive layer on a temporary substrate by electrocasting and grinding processes, and then connecting the substrate to the main member to form the probe. There also is dielectric layer between the main member and the probe. Therefore, the present invention is easier to control the size and hardness of each probe to make the probes having well strength, hardness and electric property.

At least a circuit provided at the main member and connected to the conductive layer, wherein the circuit is electrically connected to an external electronic device.

### BRIEF DESCRIPTION OF THE DRAWINGS

FIG. 1 is a sketch diagram of a first preferred embodiment of the present invention, showing the method of making the probes, in which the main member is formed with an opening;

FIG. 2 is a sketch diagram of the method of the first preferred embodiment, showing the dielectric layer on the surface of the main member and the sidewall of the opening;

FIG. 3 is a sketch diagram of the method of the first preferred embodiment, showing a grinded conductive layer in the opening of the main member;

FIG. 4 is a sketch diagram of the method of the first preferred embodiment, showing a photoresist layer on the main member to be the tips;

FIG. 5 and FIG. 6 are sketch diagrams of the method of the first preferred embodiment, showing the main member being etched to form the suspended arms;

FIG. 7 is a sketch diagram showing the application of the present invention, in which the conductive layers of the probes are electrically connected to a circuit of the main member;

FIG. 8 is a sketch diagram showing the application of a second preferred embodiment of the present invention, in which ends of the probes are uprightly connected to the main member and the other end are extended above the main member;

FIG. 9 is a sectional view of a third preferred embodiment of the present invention, in which the main member has a plurality of probes;

FIG. 10 is a sketch diagram of a fourth preferred embodiment of the present invention, showing the steps of the method of making the probes, in which the conductive layers of the probes are formed on a temporary substrate;

FIG. 11 is a sketch diagram of the method of the fourth preferred embodiment, showing the temporary substrate with the seed layer (sacrificial layer);

FIG. 12 is a sketch diagram of the method of the fourth preferred embodiment, showing the photoresist on the substrate and having an opening;

FIG. 13 is a sketch diagram of the method of the fourth preferred embodiment, showing a conductive layer filled in the opening;

FIG. 14 is a sketch diagram of the method of the fourth preferred embodiment, showing the conductive layer on the substrate;

FIG. 15 is a sketch diagram of the method of the fourth preferred embodiment, showing the substrate stacked on the main member;

FIG. 16 is a sketch diagram of the method of the fourth preferred embodiment, showing the structure of the probes;

FIG. 17 is a sketch diagram of an application of the fourth preferred embodiment, showing the probes electrically connected to a circuit board by wire bonding;

FIG. 18 is a sketch diagram of another application of the fourth preferred embodiment, showing the conductive layers of the probes extruded out of the main member;

FIG. 19 is a sectional view of a fifth preferred embodiment of the present invention, showing the conductive layers and the structure layers on the suspended arms of the probes;

FIG. 20 is a sectional view of a sixth preferred embodiment of the present invention, showing the upright conductive layers of the probes on the main member;

FIG. 21 is a sketch diagram of the method of the sixth preferred embodiment, showing the main member with an opening;

FIG. 22 is a sketch diagram of the method of the sixth preferred embodiment, showing the main member with a dielectric layer;

FIG. 23 is a sketch diagram of the method of the sixth preferred embodiment, showing the conductive layer in the opening;

FIG. 24 is a sketch diagram of the method of the sixth preferred embodiment, showing the grinded main member and conductive layer;

FIG. 25 is a sketch diagram of the method of the sixth preferred embodiment, showing the photoresist on the substrate;

FIG. 27 is a sectional view of a seventh preferred embodiment of the present invention;

FIG. 28 is a sectional view of an eighth preferred embodiment of the present invention;

FIG. 29 is a sectional view of a ninth preferred embodiment of the present invention;

FIG. 30 is a sectional view of a tenth preferred embodiment of the present invention;

FIG. 31 is a sectional view of another application of the tenth preferred embodiment of the present invention;

FIG. 32 is a sectional view of an eleventh preferred embodiment of the present invention;

FIG. 33 is a sectional view of another application of the eleventh preferred embodiment of the present invention;

FIG. 34 is a sectional view of a twelfth preferred embodiment of the present invention;

FIG. 35 is a sectional view of an application of the twelfth preferred of the present invention;

FIG. 36 is a sectional view of another application of the twelfth preferred of the present invention; and

FIG. 37 is a sectional view of a further application of the twelfth preferred of the present invention.

### DETAILED DESCRIPTION OF THE INVENTION

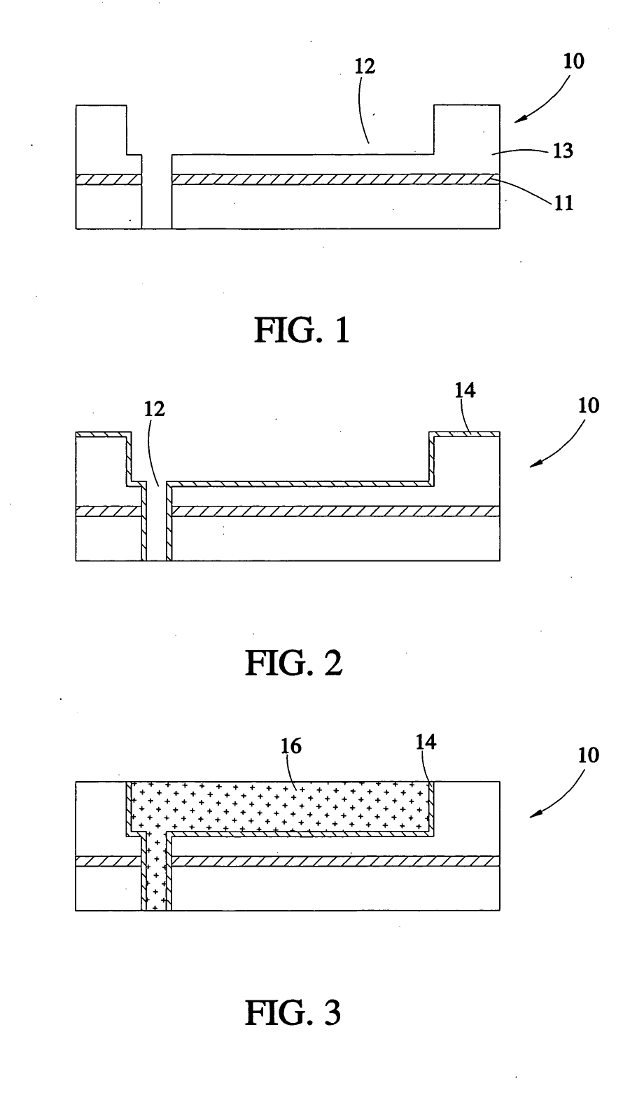

As shown in FIG. 1, a method of making probes of a probe card of the first preferred embodiment of the present invention includes the steps of:

Step 1: As shown in FIG. 1, preparing a silicon-on-insulator (SOI) main member 10, which includes a silicon substrate 13 and an insulating layer 11 embedded in the silicon substrate 13. And then, performing the semiconducting photo lithography and etching process on the main member 10 to form a via 12 thereon. The via 12 is for electrocasting probes and wires in the following steps.

Step 2: As shown in FIG. 2, forming a dielectric layer 14 on the main member 10 and on a sidewall of the via 12 in a high temperature stove or by film deposition.

Step 3: As shown in FIG. 3, performing electrocasting process on the main member 10 to fill the opening 12 with a conductive layer 16. And then, grinding the main member 10 and the dielectric layer 14 to even the main member 10 and the conductive layer 16. It may perform photo-etching, electrocasting and grinding processes alternately on the conductive layer 16 to build the conductive layer 16 with a top higher than the main member 10 also. If needed in the process, it may provide a conductive seed layer on a surface of the opening 12 prior to electrocast the main member that will make the electrocasting process easier.

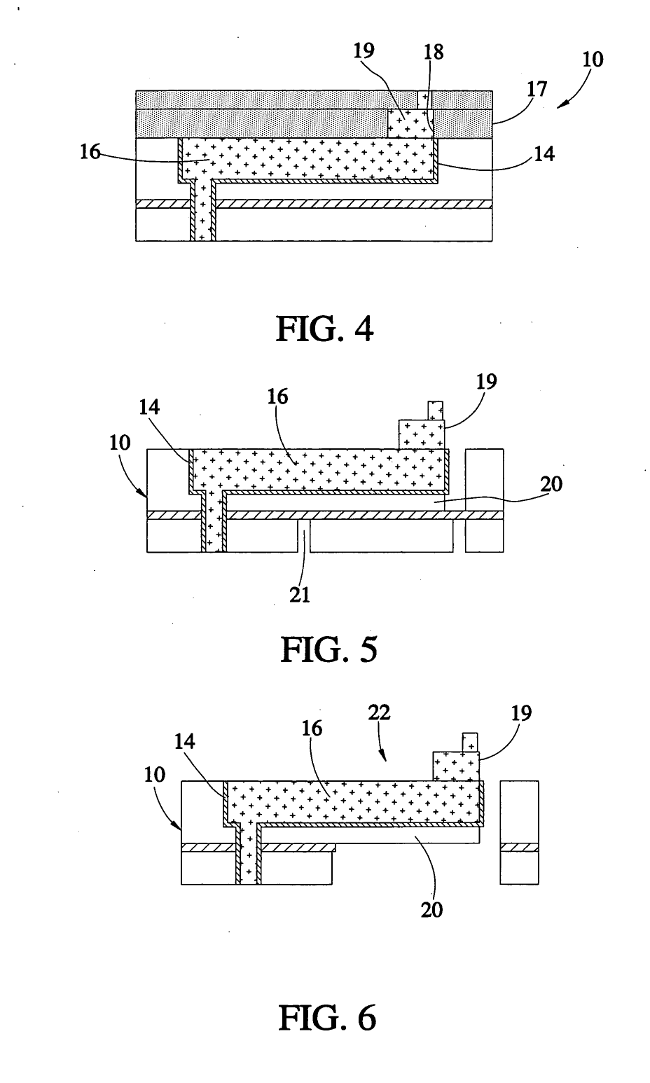

Step 4: As shown in FIG. 4, multi-photo-lithography process is performed on the conductive layer 16 to coat a photoresist layer 17. The photoresist layer 17 has a via 18 and the via 18 is filled by electrocasting to form a tip 19. The tip 19 may be incorporated in continuous electrocasting by different materials to have the properties of low viscosity and well wearproof. At last, the dry (or wet) etching process is performed on the tip 19 to flat it. It also may be done in the photo lithography and etching process, in which the via 18 of the photoresist layer 17 is taper to form a coned tip 19 directly. The electrocasting grinding, etching or mechanical process may be performed on the tip 19 also.

Step 5: As shown in FIG. 5, the photo lithography and etching process is performed on the main member 10 to define the suspended arms 20 under the conductive layer on a front side thereof. The etching process is performed again to form recesses 21 under the suspended arms 20. At last, as shown in FIG. 6, the wet etching process is performed to remove portions of the insulating layer 11 and main member 10 under the suspended arms 20. It also may be done by the photo lithography and etching process to remove the insulating layer 11 and main member 10, such that a probe 22 with an integrated suspended arm 20 and conductive layer 16 is formed.

As shown in FIG. 6, the probe 22 made by the method of the present invention includes the suspended arm 20 projected form the main member 10 and a conductive layer 16 on the suspended arm 20. The conductive layer 16 has the tip 19 on a distal end of the suspended arm 20 and a dielectric layer 14 is between the conductive layer 16 and the suspended arm 20 for insulation. The main member 10 and the suspended arm 20 are made of silicon material, and the conductive layer 16 and the tip 19 may be made of a material with properties of conduction, wearproof and low viscosity.

Because the conductive layer 16 of the probe 22 is formed by electrocasting and grinding, it is easy to control the thickness of the conductive layer 16 in the grinding process, such that the conductive layer 16 will have a uniform thickness to make the probes 22 having the same hardness and there will be a consistent contact resistance between the tips 19 and the pads to provide a stable test condition. Because the suspended arms 20 are made of silicon, it will not have fatigue in normal testing temperature that the probes 22 have well mechanical strength. The probes 22 of the present invention still keeps a well flatness after a long time of use, and the conductive layer 16, which has a well ductility, will enhance the silicon, which has a greater brittleness.

Therefore, the probes of the present invention have a well strength, uniform hardness and well electrical property. It also is easier to control the sizes and hardness of the probes in fabrication.

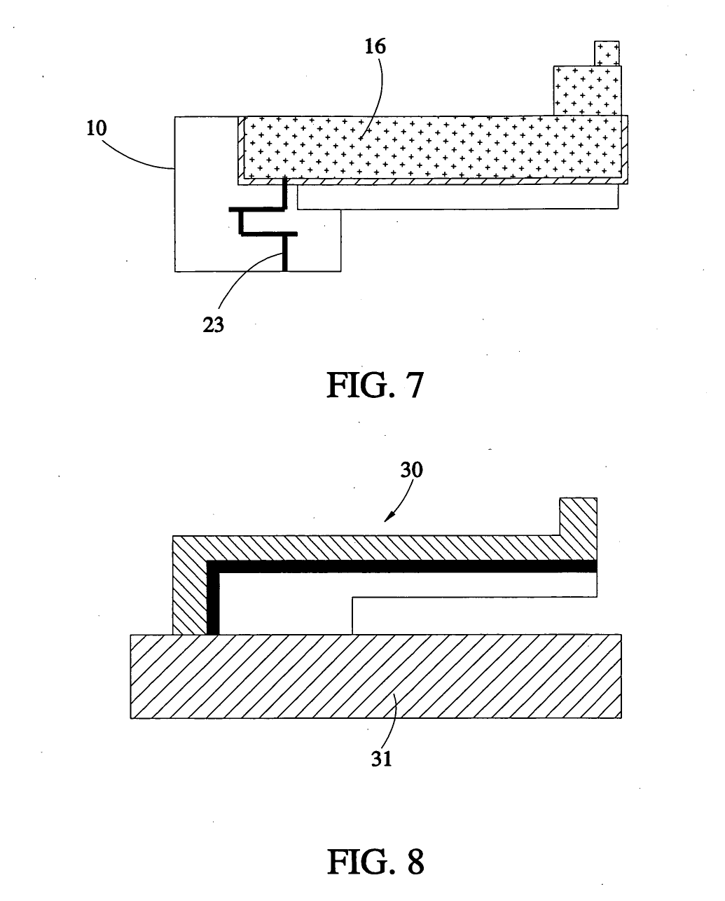

The main member and the suspended arm of the probe may be made of the same or different material. As shown in FIG. 7, the main member 10 may have a circuit 23 therein electrically connected to the conductive layer 16 and insulated from the main member 10. The circuit 23 may be electrically connected to an external electronic device (not shown). As shown in FIG. 8, a probe 30 of a probe card of the second preferred embodiment of the present invention, which the structure thereof is similar to the probe 10 of the first preferred embodiment, is a substantially L-shaped member with an upright section connected to a main member 31 and a horizontal section suspended above the main member 31.

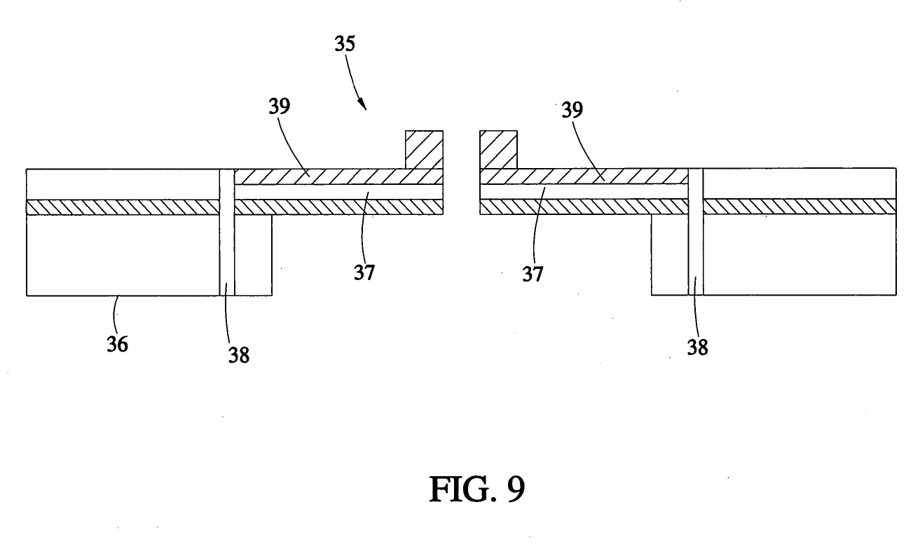

As shown in FIG. 9, a probe 35 of a probe card of the third preferred embodiment of the present invention has a main member 36 with a plurality of suspended arms 37 and circuits 38 thereon. Each circuit 38 is upright. The method of the first preferred embodiment is applied to make the probes 35 on the min member 36 directly with conductive layers 39 of the probes 35 electrically connected to the circuits 39 respectively. It also may apply wire bonding, reflow soldering, low temperature eutectic bonding or conductive paste, or the relative methods to connect the conductive layers 39 of the probes 35 and the circuits 38.

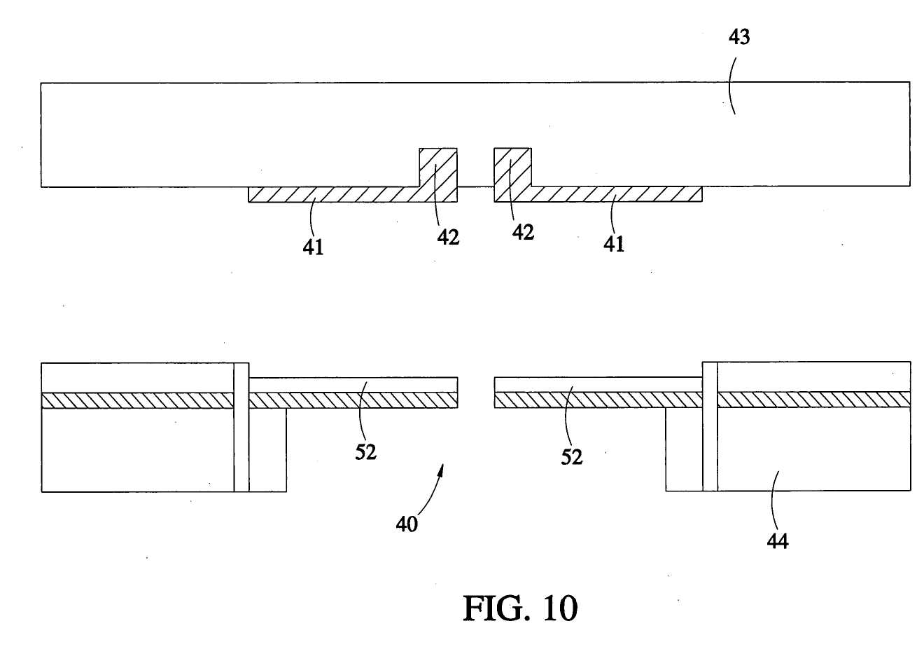

As shown in FIG. 10, a probe 40 of the fourth preferred embodiment of the present invention, which is similar to the probe 35 of the third preferred embodiment, has a conductive layer 41 and a tip 42 made on a temporary substrate 43 by yellow technique, electrocasting and grinding, and then, the conductive layers 41 are connected to the main member 44 by wafer level bonding or flip chip bonding. And then, the temporary substrate 43 is up-side-down and stacked on the main member 44 to connect the conductive layers 41 and the main member 44 by wafer level bonding or flip chip bonding. At last, the temporary substrate 43 is removed and the main member 44 is sent to next process. As a result, the structure positioning of the probes 40 keeps the precise of photo lithography process. Hereunder are the steps of the method of the fourth preferred embodiment:

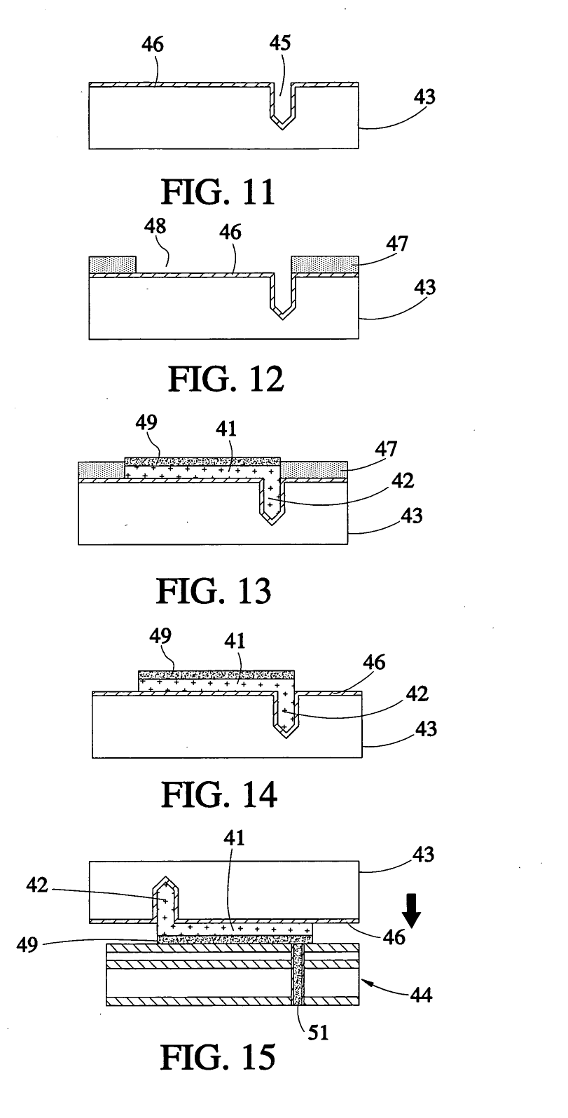

Step 1: As shown in FIG. 11, preparing the temporary substrate 43, on which a slot 45 is made by etching. If the substrate 43 is made of non-conductive material, it has to deposit a conductive seed layer 46, which has the function of sacrificial layer, on the substrate 43 for the next procedure. The seed layer 46 may be made by evaporation, sputtering or electroplating, or the relative technique. If the substrate 43 is made of conductive material, it doesn't need the seed layer but it may provide a sacrificial layer to facilitate the removal of substrate 43.

Step 2: As shown in FIG. 12, providing a photoresist 47 on the substrate 43, which has a via 48 with a predetermined shape.

Step 3: As shown in FIG. 13, filling the via 48 by electrocasting, and then grinding the substrate 43 to flat the surface thereof. Therefore, the conductive layer 41 and the tip 42 are formed. It may provide an adhesive layer 49 on the conductive layer 41 by deposition or electroplating to facilitate the adhesion process in the following steps.

Step 4: As shown in FIG. 14, removing the photoresist 47.

Step 5, As shown in FIG. 15, preparing a SOI main member 44 with vertical traces 51 and pads, and then, flipping the substrate 43 on the main member 44 with the conductive layers 41 connected to the substrate 44.

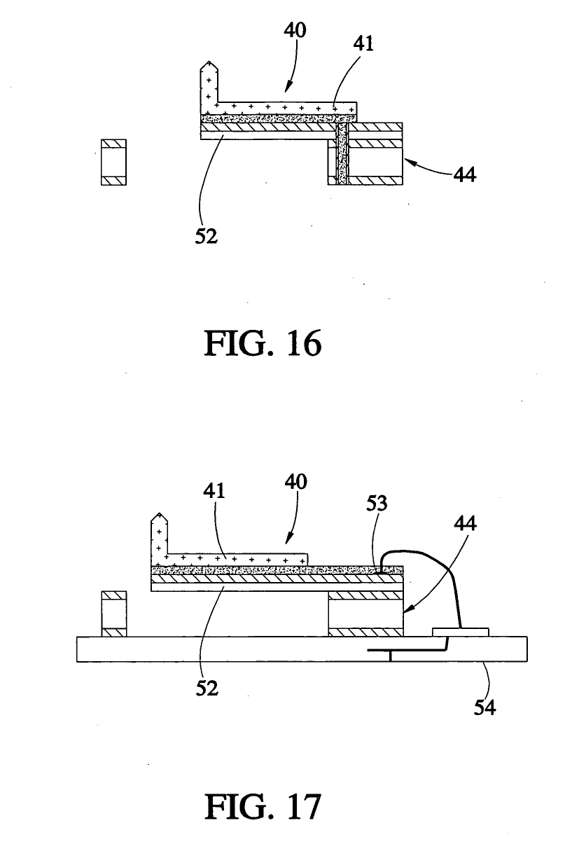

Step 6: As shown in FIG. 16, etching the seed layer 46 (or the sacrificial layer) to remove the substrate 43, and then performing semiconducting photo lithography and etching process on the main member 44 to form suspended arms 52 on a front side and etching via on a back side. At last, removing the photoresist to complete the probes 40.

As shown in FIG. 17, the main member 44 may be provided with a circuit electrically connected to the conductive layer 41. The whole probes 40 are connected to a circuit board 54 with the conductive layers 41 of the probes 40 are electrically connected to the circuit board 54 through the circuits 53 by wire bonding or welding after Step 6 of the method of the fourth preferred embodiment.

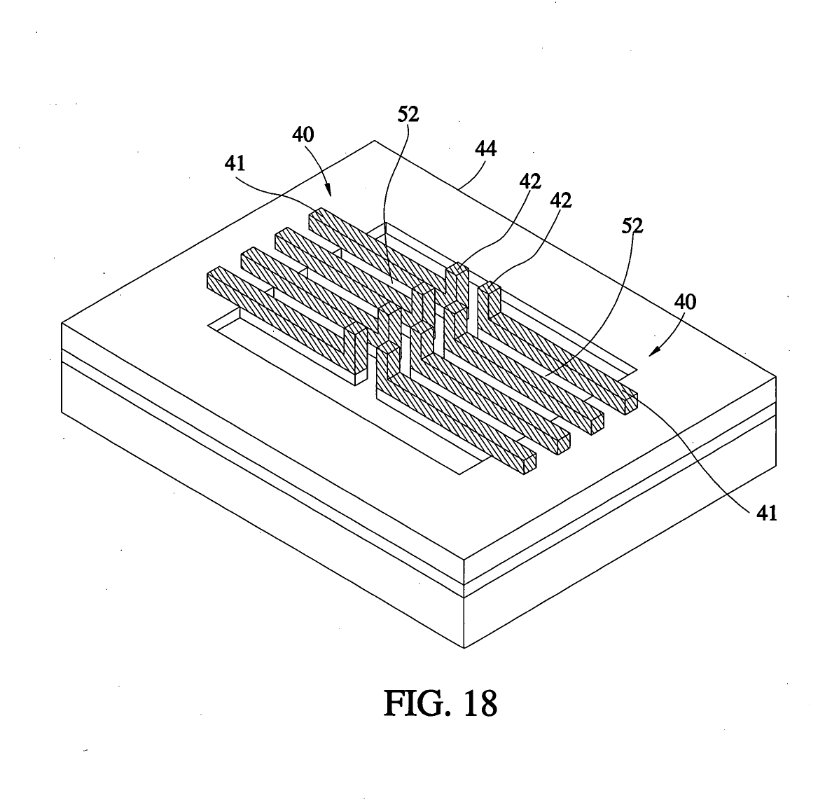

As shown in FIG. 18, each probe 40 may have a part or whole of the conductive layer 41 extruded out of the main member 44. The probe 40 of FIG. 18 may be made by the method of the first preferred embodiment to make the probes on the main member 44 directly. It also may be made by the method of the fourth preferred embodiment to independently make the conductive layers 41 and the tips 42 of the probes on the temporary substrate, and then connect to the suspended arms 52 of the main member 44, and finally remove the temporary substrate to complete the probes 40.

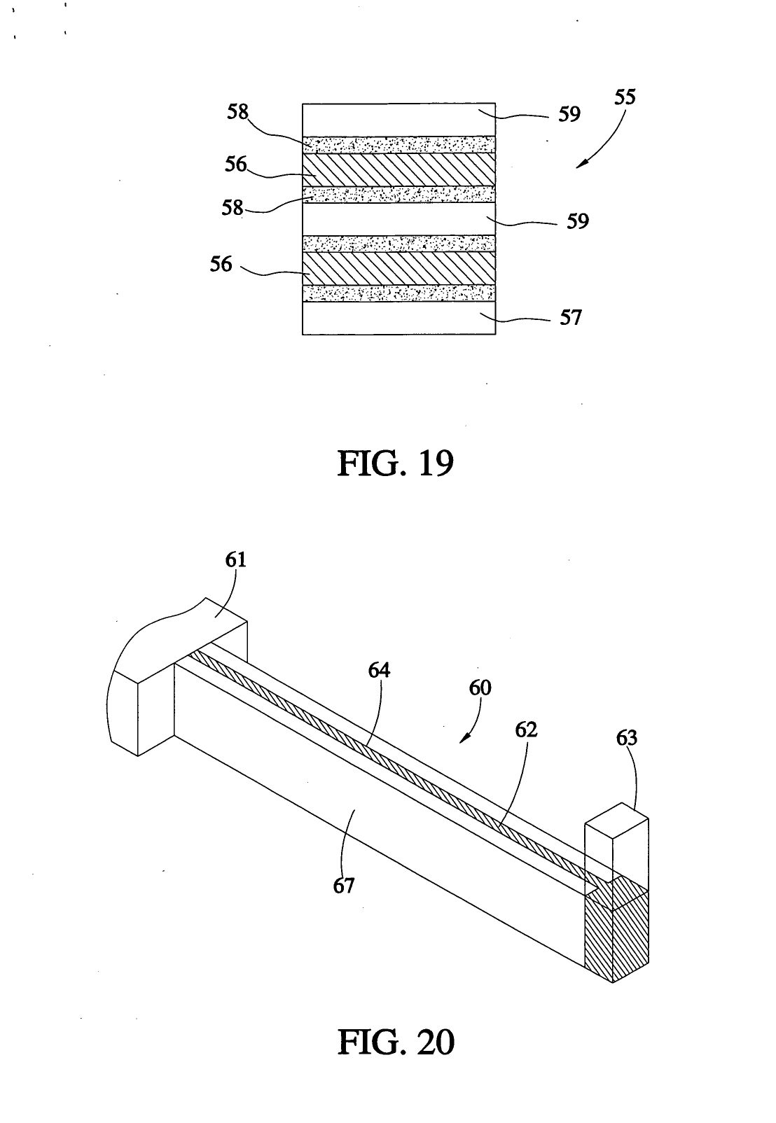

With the methods of the present invention, the suspended arms of the probes may have various structures, but the purposes are the same, to stack the silicon and metal and adjust the thickness of the conductive layers by electrocasting and grinding. As a result, the probes will have consistent hardness and electric property. As shown in FIG. 19, a probe 55 of a probe card of the fifth preferred embodiment of the present invention has a stack on the suspended arm 57. The stack includes two conductive layers 56 and two structure layers 59 stacked alternately and a dielectric layer 58 between each structure layer 59 and conductive layer 56 for insulation. The process is similar to CMOS process. The suspended arm 57 may be made of monocrystalline silicon or polycrystalline silicon. The conductive layers 56 may be used for signal transmission and grounding to improve the resistance matching of the probes 55 for the high frequency test.

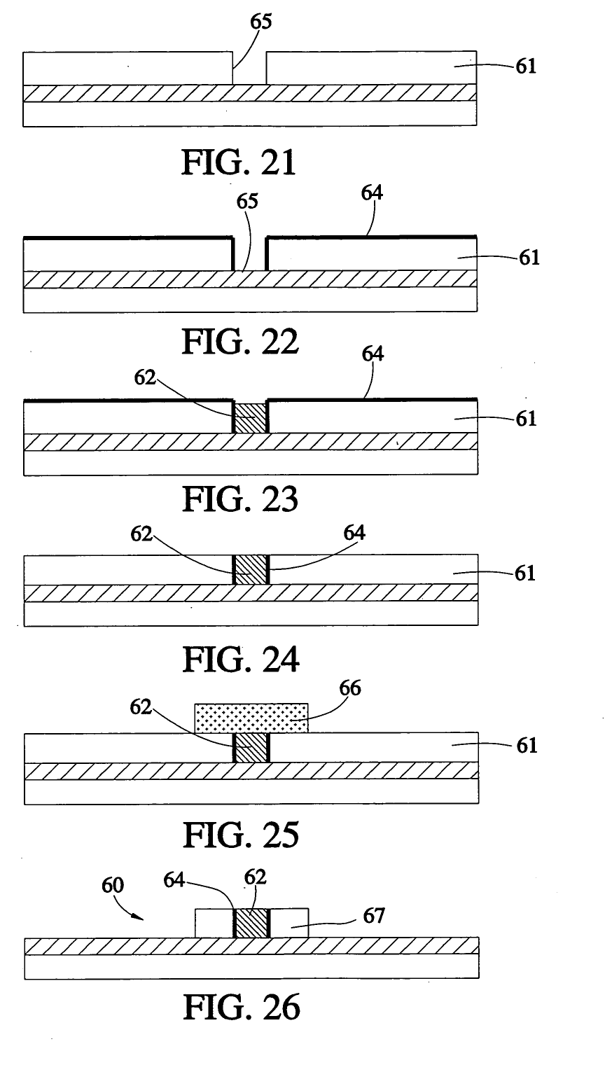

As shown in FIG. 20 and FIG. 21, a probe 60 of a probe card of the sixth preferred embodiment of the present invention includes a main member 61, a conductive layer 62, a tip 63 (only show the perspective aspect to locate the position in figure) and a dielectric layer 64. The character of the probe 60 is that a suspended arm 67 the main member 61 has a slot 65 open at both of a top and a bottom of the suspended arm 67, in which the conductive layer 62 is received. The dielectric layer 64 is between the conductive layer 62 and the suspended arm 67. The steps of making the probe 60 include:

Step 1: As shown in FIG. 21, making a slot 65 on a SOI main member with a circuit by etching.

Step 2: As shown in FIG. 22, providing the dielectric layer 64 on the main member and a sidewall of the slot 65 by chemical gas deposition or high temperature stove process. The dielectric layer 64 may be made of silicon dioxide or silicon nitride.

Step 3: As shown in FIG. 23, providing a conductive seed layer (not shown) on the dielectric layer 64 in the slot 65, and then provide the conductive layer 62 in the slot 65 by electrocasting. The seed layer may be made by connecting the circuit in the main member 61 to the electrocasting machine directly.

Step 4: As shown in FIG. 24, grinding the main member 61 and the conductive layer 62 to flat the main member 61 and the conductive layer 62.

Step 5: As shown in FIG. 25, providing a photoresist 66 on the main member 61 and the conductive layer 62. The region where the photoresist 66 covers is the aspect of the probe.

Step 6: As shown in FIG. 26, etching the main member 61 to form a suspended arm 67 on opposite sides of the conductive layer 62. The probe 60 is formed in this step.

Step 7: Performing Step 4 to Step 6 of the method of the first preferred embodiment to make the tip 63.

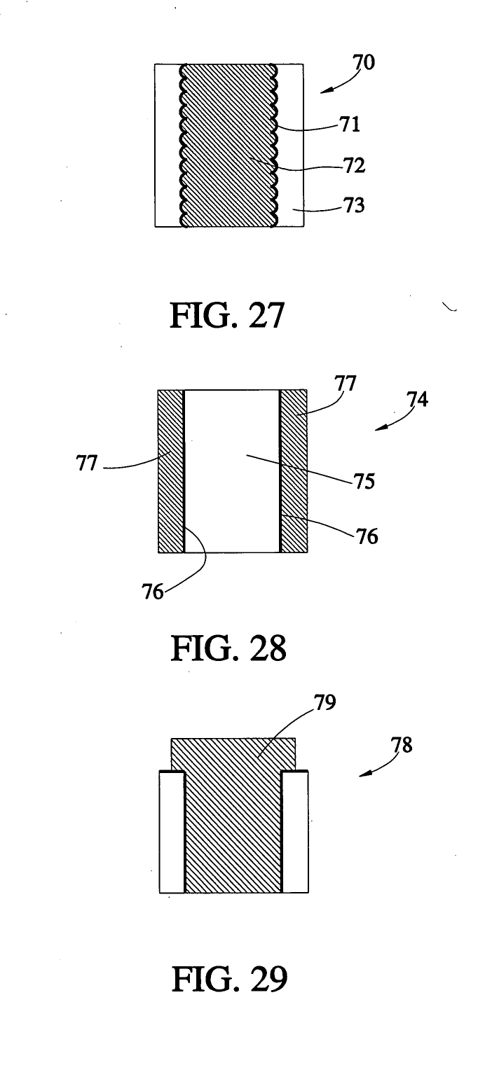

FIG. 27 shows a probe 70 of a probe card of the seventh preferred embodiment of the present invention, which is similar to the probe 60 of the sixth preferred embodiment. The character of the probe 70 is that there are a waved section of a dielectric layer 71 and a conductive layer 72 bonded to a main member 73. The waved section is made by chemical dry etching, such as ICP-RIE). The waved section provides a strong bonding strength between the main member 73, the dielectric layer 71 and the conductive layer 72. The waved section may be incorporated in every embodiments of the present invention.

The probes of the sixth and seventh preferred embodiments may be made by the above method and made into various types of probes. FIG. 8 shows a probe 74 of the eighth preferred embodiment, which character is that a dielectric layer 76 and a conductive layer 77 are provided on opposite sides of a main member 75. FIG. 29 shows a probe 78 of the ninth preferred embodiment of the present invention, which is similar to the probe 60 of the sixth preferred embodiment. The character is that the probe 78 has a conductive layer 79, which is made by electrocasting process, covered thereon to make the probe 78 has a substantially T-shaped aspect in cross-sectional view. The T-shaped structure enhances the hardness of the probe 78.

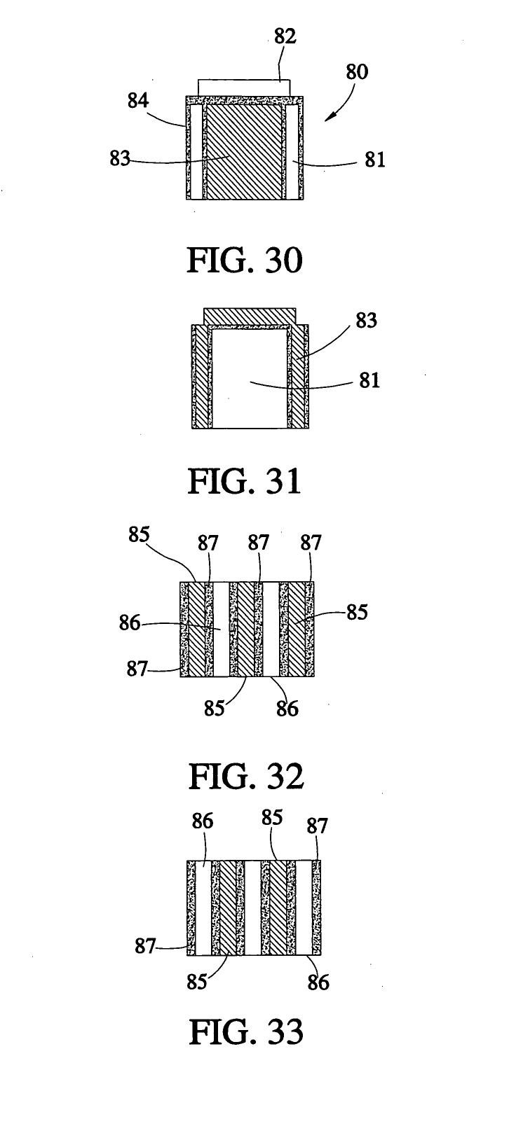

FIG. 30 shows a probe 80 of the tenth preferred embodiment of the present invention, which is similar to the probe 60 of the sixth preferred embodiment. The character is that the probe 80 is provided with a structure layer 82, which is similar to the main member 81. The structure layer 82 is made of polycrystalline silicon but the tip has to be made of metal and electrically connected to the conductive layer 83 in the main member 81. Before providing the structure layer 82, it may provide an insulating layer, such as a silicon dioxide layer, for insulation of the conductive layer 83. The main member 81 and the structure layer 82 may increase the hardness of the probe. It also can prevent the probe 80 from short and burn by the outer dielectric layer 84. For the same principle, the width of the structure layer 82 is less than the probe 80 that prevent the neighboring probes from unexpected contact, which may cause the probes short and burn.

FIG. 31 show a probe, which is similar to the tenth preferred embodiment, except that the materials of the main member 81 and dielectric layer 83 are exchanged.

FIGS. 32 and 33 show a probe of the eleventh preferred embodiment of the present invention, which is an extended embodiment of the sixth preferred embodiment. The probe has more vertical conductive layers 85. The conductive layers 85 are designated for signal lines and grounding line to reduce the noise, improve the resistance matching and increase the transmission band width. There are dielectric layers 87 between the main member 86 and the conductive layers 85 also. There also may be dielectric layers on the outer sides to prevent the neighboring probes from unexpected contact.

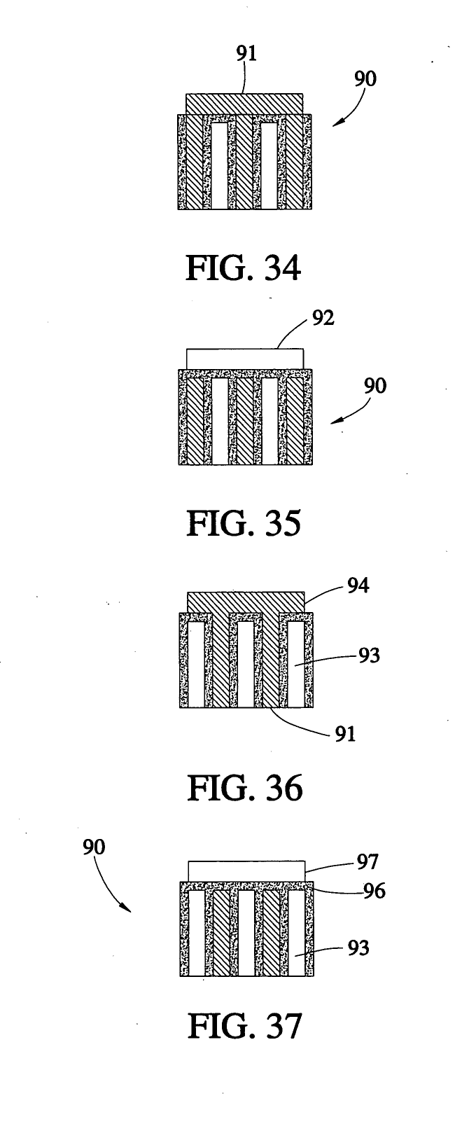

FIG. 34 shows a probe 90 of the twelfth preferred embodiment of the present invention, which is similar to the eleventh preferred embodiment. The character is that the probe 90 is provided with a conductive layer 91 on a top thereof or is provided with a structure layer 92 as shown in FIG. 35. FIG. 36 shows the probe 90 having the conductive layers 91 between suspended arms 93 and a conductive layer 94 on a top thereof. FIG. 37 shows the probe 90 having a dielectric layer 96 and a structure layer 97 on a top thereof. The character of the material of the structure layer 97 is similar to the suspended arms 93. If the suspended arms 93 are made of silicon, the structure layer 97 may be polycrystalline silicon. The main character of the probes is provided with a T-shaped or U-shaped structure to increase the hardness of the probes. All of the probes described in the embodiments of the present invention can achieve the objective of the present invention.

What is claimed is:

1. A probe of a probe card, comprising:
a main member having a suspended arm, wherein the suspended arm has a surface;
at least one conductive layer provided on the surface of the suspended arm;
a tip provided on one of the at least one conductive layer and electrically connected to the conductive layer; and
at least a circuit provided at the main member and connected to the conductive layer, wherein the circuit is electrically connected to an external electronic device.

2. The probe as defined in claim 1, wherein the main member is made of silicon.

3. The probe as defined in claim 1, wherein the suspended arm is made of silicon.

4. The probe as defined in claim 1, wherein the main member is made of an insulating material.

5. The probe as defined in claim 1, wherein a material made of the main member is different from that of the suspended arm.

6. The probe as defined in claim 1, wherein the suspended arm has a vertical section and a horizontal section, and the vertical section has an end connected to the main member and the horizontal section is suspended on the main member.

7. The probe as defined in claim 1, wherein the main member has a substantially vertical slot, in which the conductive layer is provided.

8. The probe as defined in claim 7, further comprising a conductive layer covering the suspended arm and the at least one conductive layer.

9. The probe as defined in claim 8, wherein the conductive layer has a substantial T shape in a cross-sectional view.

10. The probe as defined in claim 1, further comprising a dielectric layer on an outer side to prevent the probe from short.

11. The probe wrench as defined in claim 1, further comprising a dielectric layer between the at least one conductive layer and the suspended arm.

12. The probe as defined in claim 1, further comprising a structure layer between two of the conductive layers for insulation of the conductive layers.

13. The probe as defined in claim 12, wherein the structure layer is made of polycrystalline silicon and has a dielectric layer.

14. The probe as defined in claim 12, wherein the conductive layers are electrically connected to each other

15. The probe as defined in claim 12, wherein the conductive layers are insulated from each other.

16. A method of making the probe as defined in claim 1, comprising the steps of:
a. preparing the main member;
b. providing a dielectric layer on the main member;
c. providing the at least one conductive layer on the dielectric layer by electrocasting and grinding flatting processes;
d. providing the tip on one of the at least one of the conductive layer by photoresist, electrocasting and flatting processes; and
e. performing etching process on the main member to form the suspended arm under the at least one of the conductive layer.

17. The method as defined in claim 16, wherein the tip is made by etching process.

18. The method as defined in claim 17, wherein the tip is made by photo lithography process to form a coned via and apply electrocasting process to form a predetermined shape.

19. The method as defined in claim 16, wherein further provide a conductive layer on the suspended arm by photoresist, electrocasting and flatting processes after step c.

20. The method as defined in claim 16, wherein further provide a structure layer on the suspended arm by photoresist, electrocasting and flatting processes after step c.

21. The method as defined in claim 16, wherein the main member is made of polycrystalline silicon.

22. The method as defined in claim 20, further comprising the step of repeating step c to provide a stack including the structure layers and the conductive layer stacked alternately.

23. The method as defined in claim 22, wherein the conductive layers are electrically connected to each other

24. The probe as defined in claim 22, wherein the conductive layers are insulated from each other.

25. The probe as defined in claim 20, further comprising the step of providing a dielectric layer between the structure layer and the conductive layer while the structure layer is made of a non-insulating material.

26. A method of making the probe as defined in claim 1, comprising the steps of:
a. preparing a temporary substrate;
b. etching the temporary substrate to have a via;
c. making the at least one conductive layer and the tip on the temporary substrate by electrocasting and grinding flatting process;
d. providing the main member and connecting the at least one conductive layer of the temporary substrate to the main member and providing a dielectric layer between the at least one conductive layer and the main member;
e. removing the temporary substrate; and
f. performing semiconducting etching process on the main member to form the suspended arm.

27. The method as defined in claim 26, wherein the temporary substrate is made of a non-conductive material and is provided with a conductive seed layer before the electrocasting process.

28. The method as defined in claim 26, further providing a sacrificial layer after step b, and removing the sacrificial layer to remove the temporary substrate in step c.
